(19) United States
(12) Patent Application Publication
(10) Pub. No.: US 2004/0022664 A1
(43) Pub. Date: Feb. 5, 2004

(54) Aluminum alloy thin film and wiring circuit having the thin film and target material for forming the tin film

(76) Inventors: Takashi Kubota, Saitama (JP); Hiroshi Watanabe, Saitama (JP)

Correspondence Address: ROTHWELL, FIGG, ERNST & MANBECK, P.C., 1425 K STREET, N.W., SUITE 800, WASHINGTON, DC, 20005, US

(21) Appl. No.: 10/416,957

(22) PCT Filed: Sep. 12, 2002
(86) PCT No.: PCT/JP02/09331

(30) Foreign Application Priority Data
Sep. 18, 2001 (JP) 2001-283306

(51) Int. Cl. B32B 15/20; C23C 14/14; C23C 14/34

(52) U.S. Cl. 420/550; 428/650; 420/548

(57) ABSTRACT

The present invention intends to provide an aluminum alloy thin film that has an electrode potential of the same level as the electrode potential of an ITO film, does not diffuse silicon, has a low resistivity, and excels in heat resistance. The present invention is characterized in an aluminum alloy thin film containing 0.5 to 7.0 at % at least one or more element among nickel, cobalt, and iron, 0.1 to 3.0 at % carbon, and the balance being aluminum. Furthermore, the aluminum alloy thin film further contains 0.5 to 2.0 at % silicon.

### TECHNICAL FIELD

The present invention relates to an aluminum alloy thin film, and a sputtering target material for the formation of an aluminum alloy thin film and, more specifically, to an aluminum alloy thin film having a high heat resistance and a low electrical resistance for constituting a thin-film wiring of a liquid-crystal display, an electrode, and a wiring of a semiconductor integrated circuit; and to a sputtering target material suitable to the formation of such an aluminum alloy thin film.

### BACKGROUND ART

In recent years, liquid-crystal displays have widely been used in computers exemplified by the display devices of note-type personal computers, as the substitution of so-called Braun tubes (CRTs), and progress in the manufacture of larger and finer screens is remarkable. Consequently, in the field of liquid-crystal displays, demands for liquid-crystal displays using thin film transistors (hereafter abbreviated as TFTs) have increased, and the improvement of properties of liquid-crystal displays has also increasingly become strict. In particular, accompanying the manufacture of liquid-crystal displays with larger and finer screens, wiring materials having low resistivity have been demanded. The property requirement for resistivity is for preventing the occurrence of signal delay when longer and finer wirings are used.

Heretofore, a high-melting-point metal, such as tantalum, chromium, titanium, and the alloys thereof has been used as the wiring material for liquid-crystal displays; however, since such a high-melting-point metal has an excessively high resistivity, it is not suitable for the wiring of liquid-crystal displays with larger and finer screens. Therefore, aluminum has attracted attention as a wiring material for its low resistivity and ease of the wiring process. However, since the melting point of aluminum is as relatively low as 660° C., a problem of heat resistance arises. Namely, when an aluminum film is formed on a substrate by sputtering and processed as wiring, and then an insulating film is formed by a CVD method, the aluminum thin film processed as wiring is exposed to a heat of 300 to 400° C., and at this time bumpy protrusions, called hillocks, are produced on the surface of the aluminum film.

These hillocks pierce the insulating film, and cause short-circuiting to upper layers and between adjacent wirings, resulting in defects. Therefore, a number of aluminum alloys preventing the occurrence of hillocks by containing other elements have been developed. For example, a thin film of an aluminum alloy, such as aluminum-titanium, can reliably inhibit hillocks by controlling the content of elements such as titanium. However, if an element of a high-melting-point material as described above is added, resistivity elevates.

Taking these into consideration, the present inventors have developed a thin film of an aluminum alloy containing carbon and manganese (refer to Japanese Patent Application Laid-Open No. 2000-336447). This thin film of the aluminum alloy containing carbon and manganese has a significantly reduced hillock occurrence and a very low resistivity property, and much suitable as a thin film constituting a TFT.

However, when a TFT is constituted as a switching element of a liquid-crystal display, the ohmic contact of an ITO (indium tin oxide) film, which is a typical transparent electrode, with an aluminum alloy thin film is required. When an aluminum thin film or an aluminum-alloy thin film is directly joined to an ITO film, the aluminum is oxidized and the ITO is reduced at the joining boundary, and the joining resistance changes. This is known to be a phenomenon due to an electrochemical reaction caused by difference in electrode potentials between the aluminum or aluminum-alloy thin film and the ITO film. Therefore, the normal practice is to make a high-melting-point material such as molybdenum intervene as a barrier layer; that is, to form an aluminum-alloy thin film/molybdenum/ITO laminated structure. Since such a laminated structure leads to the elevation of manufacturing costs, an aluminum-alloy thin film having properties that can improve TFT constitution is presently required.

### DISCLOSURE OF THE INVENTION

The present invention has been devised on the basis of the above-described situations, and an object of the present invention is to provide an aluminum-alloy thin film that can be joined directly to an ITO film with ohmic contact, prevents the mutual diffusion of silicon and aluminum, has a low resistivity, and excels in heat resistance. Another object of the present invention is to provide a sputtering target suited to form an aluminum-alloy thin film having such properties.

The present inventors found, as a result of examinations wherein various elements were added to an aluminum alloy containing carbon, that the above-described objects could be achieved when the alloy composition of the an aluminum-alloy thin film was made as described below.

The present-invention is characterized in an aluminum alloy thin film containing 0.5 to 7.0 at % at least one or more element among nickel, cobalt, and iron, 0.1 to 3.0 at % carbon, and the balance being aluminum.

According to the studies of the present inventors, it was found that when at least one element of nickel, cobalt, and iron was contained in aluminum, the electrode potential of the aluminum-alloy thin film became the same level as the electrode potential of an ITO film. The present inventors also ascertained that these elements and carbon are contained, the generation of hillocks could be prevented, and an aluminum-alloy thin film having a low resistivity could be formed. Although the “electrode potential” means a potential when the rate of oxidation and the rate of reduction come to equilibrium in a redox reaction of certain reacting substances, known as equilibrium potential; or a self-potential; it means herein a self-potential. The self-potential is a potential against a reference electrode in the state where no power is supplied to the measuring system, that is, in a natural state when certain reacting substances are immersed in an aqueous solution.

According to the aluminum-alloy thin film of the present invention, when the aluminum-alloy thin film is joined to an ITO film with ohmic contact, the aluminum-alloy thin film can be joined directly to the ITO film without providing a high-melting-point material such as molybdenum, and the manufacturing process of a TFT can be simplified leading to the reduction of production costs. Also, since the aluminum-alloy thin film of the present invention excels in heat resistance, and has a low resistivity, wirings suitable to larger and finer liquid-crystal displays can be formed.

The aluminum-alloy thin film of the present invention may contain any one of nickel, cobalt, and iron; and also may contain two or more thereof. The content within a range between 0.5 and 7.0 at % can realize favorable properties. If the content is less than 0.5 at %, the electrode potential of the aluminum-alloy thin film differs from that of the ITO film to a large extent, and the aluminum-alloy thin film cannot be joined directly to the ITO film, lowering the heat resistance of the thin film. If the content exceeds 7.0 at %, the resistivity exceeds 20 μΩ·cm after a heat treatment in vacuum at 300° C. for an hour, even if the aluminum-alloy thin film is formed at a substrate temperature of 200° C., and a wiring material practically used in liquid-crystal displays cannot be obtained.

According to the study of the present inventors, in the aluminum-alloy thin film of the present invention when only nickel is contained in aluminum-carbon, the range between 0.5 and 5 at % is more preferable. Within this range, a thin film having a low resistivity and favorable heat resistance can be obtained, which is very suitable as a wiring material for larger and finer liquid-crystal displays. For the same reason, when only cobalt or iron is contained in aluminum-carbon, the range between 2.0 and 5.0 at % is more preferable.

Carbon contained in the aluminum-alloy thin film of the present invention within the range between 0.1 and 3.0 at % realizes favorable properties. If the content of carbon is less than 0.1 at %, the effect of inhibiting the generation of hillocks is lost; and if it exceeds 3.0 at %, resistivity is elevated, and a wiring practical to liquid-crystal displays cannot be obtained.

It is preferable that the aluminum-alloy thin film of the present invention also contains 0.5 to 2.0 at % silicon. It has been known that when an aluminum-alloy thin film is directly joined to silicon, the mutual diffusion of aluminum and silicon occurs at the joining boundary (Reference document: “Thin Film Technology of VLSIs” published by Maruzen in 1986). Therefore, when silicon is previously contained in an aluminum-alloy thin film, the mutual diffusion of aluminum and silicon can be effectively prevented. If the content of silicon is less than 0.5 at %, the effect of preventing the mutual diffusion at the joining-boundary lowers; and the content of silicon exceeding 2.0 at % is not preferable because silicon or silicon deposits become etching residues.

The above-described aluminum-alloy thin film according to the present invention is very suitable as the wiring materials when a thin-film wiring for liquid-crystal displays, electrode, a wiring for semiconductor integrated circuits, and the like. This is because when a TFT is constituted, the aluminum-alloy thin film according to the present invention can be formed directly on an ITO film to make ohmic contact without forming a barrier layer of a high-melting-point material such as molybdenum. When the TFT has been formed, the mutual diffusion of the aluminum alloy and silicon can be prevented.

When the aluminum-alloy thin film according to the present invention is formed, as described above, it is preferable to use a target material for forming an aluminum-alloy thin film containing 0.5 to 7.0 at % at least one or more element among nickel, cobalt, and iron, 0.1 to 3.0 at % carbon, and the balance being aluminum; and is more preferable to use a target material further containing 0.5 to 2.0 at % silicon. When the target material of this composition is used, although influenced by film forming conditions, a thin film having the same composition as the composition of the target material can be formed easily by sputtering.

Although it is preferable that the aluminum-alloy thin film according to the present invention is formed using the target material having the above-described composition, the target material is not limited to a single target material containing all the required elements. For example, a composite target material wherein chips of nickel iron, and cobalt are buried in the surface of the target material of an aluminum-carbon alloy may be used; or, a composite target material wherein a carbon chip or the chips of nickel or the like are buried in the surface of the target material of a pure aluminum may also be used. In brief, any target materials can be used as long as a thin film within the composition range of the aluminum-alloy thin film according to the present invention can be obtained, and an optimal target material can be optionally selected considering the sputtering equipment and conditions.

### BEST MODE FOR CARRYING OUT THE INVENTION

The preferred embodiment of the present invention will be described with reference to examples and comparative examples.

Table 1 lists the results of examination of film compositions, film resistivities, and states of hillock generation for Examples 1A to 14A, and Comparative Examples 1 and 2.

Thin films of composition of Examples 1A to 14A shown in Table 1 were formed using a target material manufactured as follows:

First, aluminum of a purity of 99.99% was charged into a carbon crucible (purity: 99.9%), and heated to a temperature range between 1600° C. and 2500° C. to melt the aluminum. The melting of the aluminum in the carbon crucible was performed in an argon gas atmosphere under an atmospheric pressure. After maintaining the melting temperature for about 5 minutes to form an aluminum-carbon alloy in the carbon crucible, the melt was charged into a carbon mold, and was allowed to stand for natural cooling to cast the alloy.

The ingot of the aluminum-carbon alloy cast in the carbon mold wad taken out, predetermined quantities of aluminum and nickel having a purity of 99.99% were added, the mixture was charged into a carbon crucible and heated to 800° C. for re-melting, and stirred for about 1 minute. This re-melting was also performed in an argon gas atmosphere under an atmospheric pressure. After stirring, the melt was cast in a copper water-cooling mold to obtain a target material of a predetermined shape. The dimension of the final target material was 100 mm in diameter and 6 mm in thickness.

With the use of this target material, sputtering was performed under the thin-film forming conditions described below, and the analysis of the obtained thin film showed that the thin film was composed of 1.9 at % nickel, 0.8 at % carbon, and the balance being aluminum (Example 5).

The thin film was formed with the use of Corning #1737 glass plate of a thickness of 0.8 mm as a substrate, under conditions of an input power of 3.0 Watt/cm², an argon gas flow rate of 20 ccm, an argon pressure of 2.5 mTorr, using magnetron sputtering equipment for a film-forming time of about 150 sec, and a thin film of a thickness of about 3000 Å (about 0.3 μm) was formed on the glass plate. The substrate temperature was 100° C. or 200° C.

With the use of the above-described method, target materials of various compositions were prepared, and with the use of the target materials of carious compositions, thin films of examples listed in Table 1 were formed. The film composition of each thin film shown in Table 1 was quantitatively determined by means of ICP optical emission spectrometry (inductively-coupled plasma emission spectrometry) for nickel, cobalt, iron, and silicon; and a carbon analyzer for carbon. The resistivity of each thin film was measured with the use of a 4-terminal resistance measuring apparatus. (measuring current: 100 mA). The resistivity was measured immediately after sputtering (as-dope), and after each glass plate carrying the thin film had been heat-treated for 1 hour at 3 levels of 300° C., 350° C.; and 400° C. in vacuum. The results were as shown in Table 1.

The state of hillock generation was evaluated by observing the surface of each film after the above-described 3-level heat treatment using a scanning electron microscope (SEM) at 1000-times, 5000-times, and 15000-times magnifications; and recorded in Table 1 with “U” (unrecognized) for the cases where no hillocks were observed in any magnification, and “R” (recognized) for the films wherein the generation of hillocks was identified at any of magnifications.

TABLE 1

| | | Substrate | Film resistivity (μΩ · cm) | | | | State of hillock generation | | |
|---|---|---|---|---|---|---|---|---|---|
| | Film composition (at %) | temperature (° C.) | as-dope | 300° C. | 350° C. | 400° C. | 300° C. | 350° C. | 400° C. |
| Example 1A | Al-0.3C-1.2Ni | 100 | 6.18 | 6.32 | 4.57 | 4.03 | U | R | R |
| Example 2A | Al-0.3C-2.3Ni | 100 | 8.66 | 6.99 | 4.86 | 4.08 | U | R | R |
| Example 3A | Al-0.3C-3.1Ni | 100 | 10.34 | 7.37 | 5.51 | 4.40 | U | U | R |
| Example 4A | Al-0.8C-0.9Ni | 100 | 6.73 | 6.78 | 6.12 | 4.23 | U | R | R |
| Example 5A | Al-0.8C-1.9Ni | 100 | 8.01 | 6.87 | 4.84 | 4.08 | U | U | R |
| Example 6A | Al-0.8C-3.2Ni | 100 | 11.80 | 7.26 | 5.12 | 3.97 | U | U | R |
| Example 7A | Al-1.9C-1.2Ni | 100 | 8.50 | 8.70 | 6.93 | 5.36 | U | R | R |
| Example 8A | Al-1.9C-1.7Ni | 100 | 10.70 | 9.26 | 5.96 | 5.01 | U | U | R |
| Example 9A | Al-1.9C-3.2Ni | 100 | 12.70 | 9.84 | 7.03 | 5.61 | U | U | U |
| Comparative | Al (5N) | 100 | 3.16 | 3.23 | 3.30 | 3.37 | R | R | R |
| Example 1A | | | | | | | | | |
| Comparative | Al-1.3C | 100 | 5.83 | 4.62 | 4.58 | 3.99 | R | R | R |
| Example 2A | | | | | | | | | |
| Example 11A | Al-1.3C-2.8Co | 100 | 14.80 | 5.75 | 5.30 | 4.43 | U | R | R |
| Example 12A | Al-1.3C-5.4Co | 100 | 24.50 | 8.90 | 8.40 | 8.05 | U | U | U |
| Example 13A | Al-1.3C-2.7Fe | 100 | 21.60 | 7.37 | 5.95 | 6.02 | U | U | U |
| Example 14A | Al-1.3C-4.6Fe | 100 | 40.10 | 10.30 | 7.37 | 7.89 | U | U | U |

As seen from Table 1, although pure aluminum films and aluminum-carbon alloy films, which were comparative examples, had low resistivities, the generation of hillocks was identified under all heat-treatment conditions. On the other hand, although some aluminum alloy thin films containing aluminum-carbon and nickel (Examples 1A to 9A) had resistivity exceeding 10 μΩ·cm immediately after sputtering, it was known that all had resistivity of less than 10 μΩ·cm after heat treatment, and had properties required in wiring materials. Also, it was known that no generation of hillocks was identified at all in the heat treatment at 300° C., and that no hillocks were generated even at 350° C. and 400° C. in some thin films.

For aluminum alloy films containing cobalt (Examples 11A and 12A) and iron (Examples 13A and 14A) other than nickel, although the resistivity immediately after sputtering was somewhat high, it was verified that they had practical resistivity as wiring materials, few hillocks were generated, and excelled in heat resistance similar to nickel.

Next, the results of aluminum alloy films formed using the substrate temperature of 200° C. in sputtering will be described. Table 2 shows the results of Examples 1B to 14B, and Comparative Examples 1B and 2B. The thin films shown in Table 2 were formed under the same conditions as in the case of Table 1, except that the substrate temperature was 200° C. Also, since the measurement of resistivity and the observation of the state of hillock generation are same as the above description, the description thereof will be omitted.

TABLE 2

| | | Substrate | Film resisitivity (μΩ · cm) | | | | State of hillock generartion | | |
|---|---|---|---|---|---|---|---|---|---|
| | Film composition (at %) | temperature (° C.) | as-dope | 300° C. | 350° C. | 400° C. | 300° C. | 350° C. | 400° C. |
| Example 1B | Al-0.3C-1.2Ni | 200 | 4.94 | 4.82 | 4.41 | 3.89 | U | R | R |
| Example 2B | Al-0.3C-2.3Ni | 200 | 6.08 | 5.07 | 4.65 | 3.95 | U | U | U |
| Example 3B | Al-0.3C-3.1Ni | 200 | 6.50 | 5.49 | 5.10 | 4.20 | U | U | U |
| Example 4B | Al-0.8C-0.9Ni | 200 | 5.05 | 4.93 | 4.97 | 4.12 | U | R | R |
| Example 5B | Al-0.8C-1.9Ni | 200 | 6.35 | 5.38 | 5.02 | 4.38 | U | U | U |
| Example 6B | Al-0.8C-3.2Ni | 200 | 8.19 | 6.35 | 5.44 | 4.92 | U | U | U |
| Example 7B | Al-1.9C-1.2Ni | 200 | 6.30 | 5.87 | 5.70 | 4.59 | U | U | U |
| Example 8B | Al-1.9C-1.7Ni | 200 | 6.67 | 6.26 | 5.84 | 5.17 | U | U | U |
| Example 9B | Al-1.9C-3.2Ni | 200 | 8.32 | 7.32 | 6.58 | 5.17 | U | U | U |
| Comparative | Al (5N) | 200 | 3.10 | 3.25 | 3.29 | 3.36 | R | R | R |
| Example 1B | | | | | | | | | |
| Comparative | Al-1.3C | 200 | 4.18 | 4.34 | 4.28 | 3.92 | R | R | R |
| Example 2B | | | | | | | | | |
| Example 11B | Al-1.3C-2.8Co | 200 | 9.87 | 6.72 | 6.37 | 4.95 | U | U | U |
| Example 12B | Al-1.3C-4.5Co | 200 | 13.80 | 9.10 | 8.63 | 8.10 | U | U | U |
| Example 13B | Al-1.3C-2.7Fe | 200 | 11.10 | 9.83 | 6.71 | 6.08 | U | U | U |
| Example 14B | Al-1.3C-4.6Fe | 200 | 15.90 | 13.70 | 9.31 | 8.93 | U | U | U |

As seen from Table 2, even when the substrate temperature was 200° C., the generation of hillocks was found in the pure-aluminum film of Comparative Example 1B and the aluminum-carbon alloy film of Comparative Example 2B under all the heat-treatment conditions, although the resistivity thereof were low. On the other hand although some aluminum alloy thin films containing aluminum-carbon and nickel (Examples 1B to 9B) had resistivity of less than 10 μΩ·cm immediately after sputtering, and after heat treatment. Also, it was known that the state of hillock generation of the thin film was better than the case where the substrate temperature was 100° C.

In the cases of cobalt (Examples 11B and 12B) and iron (Examples 13B and 14B) other than nickel, when the substrate temperature was 200° C., the resistivity was lower than the cases where the substrate temperature was 100° C., and no generation of hillock was identified.

Next, the results of measuring the self-potential of each thin film will be described. A thin film of a predetermined thickness (0.3 μm) of each composition shown in Table 3 was formed on a glass substrate, and the glass substrate was cut to prepare the samples for potential measurement. Then, the surface of the samples for potential measurement was masked so as to expose an area equivalent to 1 cm² to form an electrode for measurement. The self-potential was measured with the use of a 3.5% aqueous solution of sodium chloride (liquid temperature: 27° C.) and with the use of a silver/silver chloride reference electrode. The ITO film that became the counterpart of ohmic contact had a composition of In₂O₃-10 wt % SnO₂.

TABLE 3

| | | Self-potential |
|---|---|---|
| | Film composition (at %) | (−mV) |
| ITO | In₂O₃-10wt % SnO₃ | 1008 |
| Example 1 | Al-0.3C-1.2Ni | 920 |
| Example 2 | Al-0.3C-2.3Ni | 907 |
| Example 3 | Al-0.3C-3.1Ni | 797 |
| Example 11 | Al-1,3C-2.8Co | 674 |
| Example 15 | Al-1.3C-5.4Co | 646 |
| Example 13 | Al-1.3C-2.7Fe | 800 |
| Example 14 | Al-1.3C-4.6Fe | 875 |
| Comparative | Al (5N) | 1554 |
| Example 1 | | |
| Comparative | Al-1.1C | 1506 |
| Example 2-1 | | |
| Comparative | Al-1.3C | 1498 |
| Example 2 | | |
| Comparative | Al-1.9C | 1464 |
| Example 2-2 | | |
| Example 15 | Al-1.0C-2.1Ni-1.0Si | 798 |

As Table 3 shows, the self-potential of the ITO film was around −1000 mV. It was confirmed that the self-potential of the pure-aluminum thin film was about −1550 mV, and that of the aluminum-carbon alloy thin film was −1400 to −1500 mV. On the other hand, the aluminum-carbon alloy thin film containing nickel, cobalt, and iron had a self-potential within a range between about −650 to −1000 mV, which was substantially the same level as the self-potential of the ITO film.

Here, the evaluation test for the junction resistance of an aluminum alloy thin film of the present invention to an ITO film will be described. Under the above-described thin-film forming conditions, and using a substrate of a temperature of 100° C., an aluminum alloy thin film of a thickness of 0.3 μm was formed on a glass substrate, and a pattern electrode of 1×20 mm was formed with the use of this thin film. On this pattern electrode of the aluminum alloy thin film, an ITO-electrode pattern (1×20 mm, 0.3 μm thick) in an orthogonal state is formed to fabricate a sample for measuring junction resistance. This sample for measuring junction resistance was subjected to a heat-treatment in vacuum at 250° C. for 1 hour, and change in resistance at the junction between the aluminum-alloy thin film electrode and the ITO film electrode was checked. As a result, in the combination of pure aluminum (5N) and the ITO film, the junction resistance value after the heat treatment was about 4 times the junction resistance value before the heat treatment. Whereas, it was known, in the combination of the aluminum-carbon alloy thin film containing nickel, cobalt, and iron, and the ITO film, that the junction resistance value after the heat treatment did not change from the junction resistance value before the heat treatment.

Lastly, the evaluation of the diffusibility of an aluminum-alloy thin film of these examples and silicon will be described. An aluminum-alloy thin film of a thickness of 0.1 μm was formed on a non-doped silicon wafer of a diameter of 4 inches under the above-described thin-film forming conditions at a substrate temperature of 100° C. This sample was subjected to a heat treatment in vacuum at 250° C. for 1 hour, and the sample after the heat treatment was subjected to the analysis for each element in the depth direction from the surface side of the thin film with the use of a scanning Auger microscope. As a result, in pure aluminum (5N), the mutual diffusion of aluminum and silicon was identified at the boundary thereof. Whereas, in the thin film of an aluminum-carbon alloy containing predetermined quantities of silicon and any of nickel, cobalt, and iron, no mutual diffusion of aluminum and silicon was identified at the boundary of the aluminum alloy and silicon.

### INDUSTRIAL APPLICATION

As described above, since the aluminum alloy thin film of the present invention has a self-potential of the same level as an ITO film, the aluminum alloy thin film makes direct ohmic contact to the ITO feasible, prevents counter diffusion between silicon and aluminum, has a low resistivity, and excels in heat resistance.

1. An aluminum alloy thin film containing carbon, wherein the aluminum alloy thin film contains 0.5 to 7.0 at % at least one or more element among nickel, cobalt, and iron, 0.1 to 3.0 carbon, and the balance being aluminum.

2. The aluminum alloy thin film according to claim 1, further containing 0.5 to 2.0 at % silicon.

3. A wiring circuit having an aluminum alloy thin film according to claim 1 or 2.

4. A target material for forming an aluminum alloy thin film containing carbon, wherein the target contains 0.5 to 7.0 at % at least one or more element among nickel, cobalt, and iron, 0.1 to 3.0 at % carbon, and the balance being aluminum.

5. The target material for the formation of an aluminum alloy thin film according to claim 4, further containing 0.5 to 2.0 at % silicon.
